(19) United States
(12) Patent Application Publication
(10) Pub. No.: US 2015/0114688 A1
(43) Pub. Date: Apr. 30, 2015

(54) PRINTED CIRCUIT BOARD

(71) Applicant: Samsung Electro-Mechanics Co., Ltd., Suwon (KR)

(72) Inventor: Byung Ho KIM, Busan (KR)

(73) Assignee: Samsung Electro-Mechanics Co., Ltd., Suwon (KR)

(21) Appl. No.: 14/522,316

(22) Filed: Oct. 23, 2014

(30) Foreign Application Priority Data
Oct. 29, 2013 (KR) 10-2013-0129142

(51) Int. Cl. H05K 1/03; H05K 1/02; H05K 1/09

(52) U.S. Cl. CPC H05K 1/0306; H05K 1/092; H05K 1/0298; H05K 2201/09409
USPC 174/251

(57) ABSTRACT

Disclosed herein is a printed circuit board having an improved structure of a dummy part to improve warpage strength of the printed circuit board, the printed circuit board including: a plurality of insulating layers built-up therein, the plurality of insulating layers including copper clad layers; and a product zone and a dummy zone formed at a central part and along an edge part of the insulating layers, respectively, wherein the copper clad layers included in each insulating layer are arranged in the dummy zone at predetermined intervals in a longitudinal direction.

CROSS REFERENCE(S) TO RELATED APPLICATIONS This application claims the foreign priority benefit under 35 U.S.C. Section 119 of Korean Patent Application No. 10-2013-0129142, entitled “Printed Circuit Board” filed on Oct. 29, 2013, which is hereby incorporated by reference in its entirety into this application.

### BACKGROUND OF THE INVENTION

1. Technical Field

The present invention relates to a printed circuit board, and more particularly, to a printed circuit board having an improved warpage strength of the printed circuit board by improving a structure of a dummy part thereof.

2.Description of the Related Art

In general, a printed circuit board (PCB), which serves to electrically connect or mechanically fix electronic components to each other, includes insulating layers made of insulating materials such as a phenol resin or an epoxy resin and copper clad layers attached to the insulating layers and having predetermined wiring patterns formed thereon.

The printed circuit board is largely classified into a single PCB having the wiring patterns formed on only one surface of the insulating layer, a double PCB having the wiring patterns formed on both surfaces of the insulating layer, and a multilayer PCB having the wiring patterns formed in multilayers by stacking the plurality of insulating layers having the wiring patterns formed thereon.

Due to the recent trend toward miniaturization, thinness and high densification of the electronic component, the multilayer printed circuit board has been mainly used; however, coefficients of thermal expansion are different for each insulating layer, such that warpage in a smile shape or a crying shape is generated in a printed circuit board, and an interest in reinforcing the warpage of the printed circuit board has been increased.

However, the recently launched printed circuit boards have significant difficulties in preventing the warpage of the printed circuit board in spite of various efforts for reinforcing the warpage of the printed circuit board.

### RELATED ART DOCUMENT

### Patent Document

(Patent Document 1) Korean Patent Laid-Open Publication No. 10-2013-0011369

### SUMMARY OF THE INVENTION

An object of the present invention is to provide a printed circuit board capable of decreasing warpage of the printed circuit board by improving warpage strength of a dummy part of the printed circuit board.

Another object of the present invention is to provide a printed circuit board capable of increasing warpage strength of the printed circuit board by alternately arranging copper clad layers stacked in insulating layers in a longitudinal direction, respectively.

According to a first exemplary embodiment of the present invention, there is provided a printed circuit board including: a plurality of insulating layers built-up therein, the plurality of insulating layers including copper clad layers; and a product zone and a dummy zone formed at a central part and along an edge part of the insulating layers, respectively, wherein the copper clad layers included in each insulating layer are arranged in the dummy zone at predetermined intervals in a longitudinal direction. A glass cloth may be contained in the insulating layer.

The copper clad layers included in the dummy zone may be arranged in a lattice shape in the dummy zone, and the copper clad layers included in the dummy zone may have a square shape, respectively, or a rectangular shape, respectively.

According to a second exemplary embodiment of the present invention, there is provided a printed circuit board including: a plurality of insulating layers built-up therein, the plurality of insulating layers including copper clad layers; and a product zone and a dummy zone formed at a central part and along an edge part of the insulating layers, respectively, wherein in the dummy zone, the copper clad layers included in each insulating layer are partially overlapped with each other in a longitudinal direction. A glass cloth may be contained in the insulating layer. The copper clad layers included in the dummy zone may have a rectangular shape, respectively.

### BRIEF DESCRIPTION OF THE DRAWINGS

FIG. 1 is a view showing a cross section of a dummy part of a printed circuit board according to an exemplary embodiment of the present invention;

FIG. 2 is a view showing the entire cross section of the printed circuit board according to an exemplary embodiment of the present invention;

FIG. 3 is a view showing another printed circuit board according to another exemplary embodiment of the present invention; and

FIG. 4 is a graph showing data obtained by measuring warpage of the printed circuit board according to the exemplary embodiment of the present invention.

### DESCRIPTION OF THE PREFERRED EMBODIMENTS

Hereinafter, preferred exemplary embodiments of the present invention will now be described in detail with reference to the accompanying drawings.

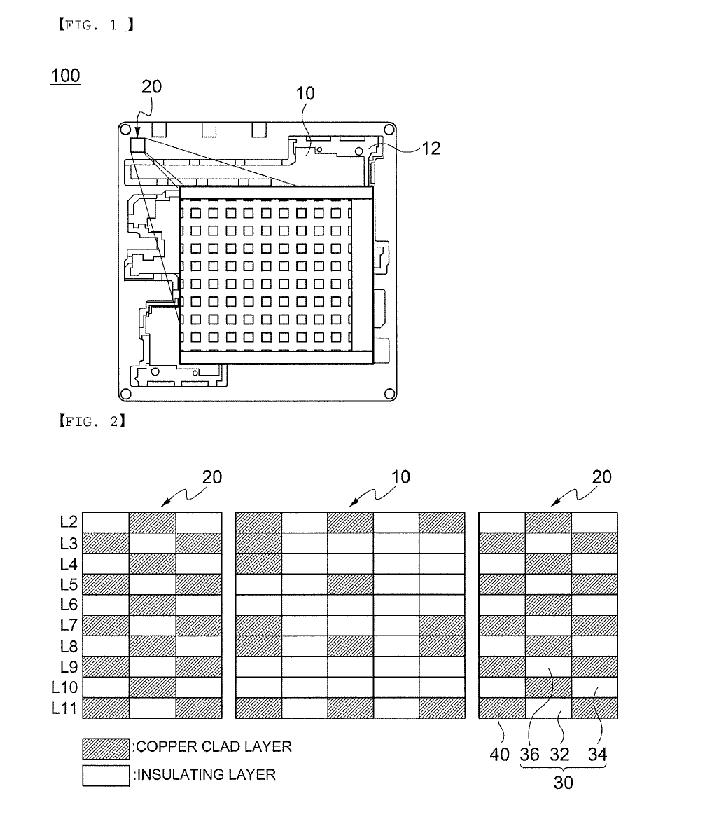

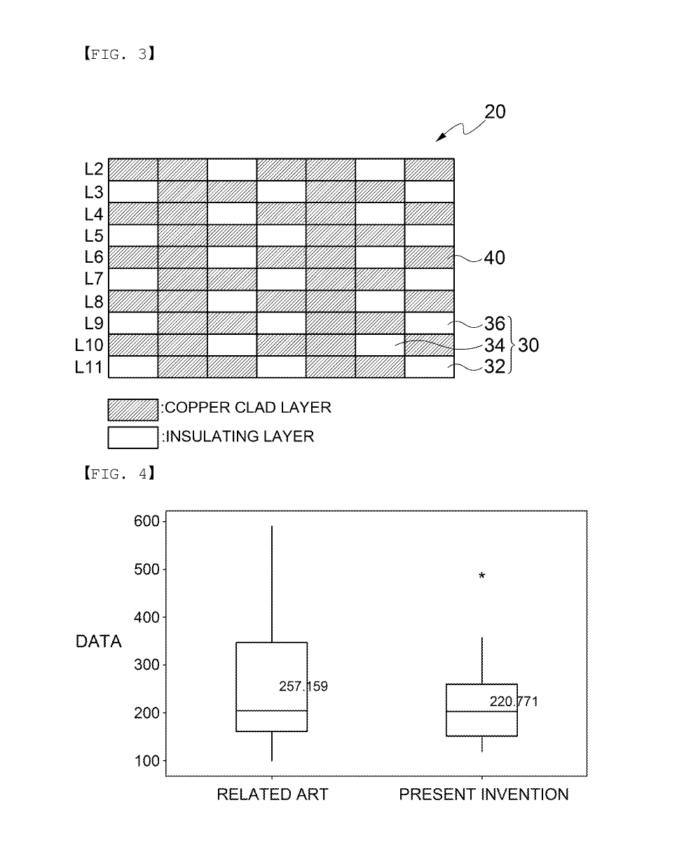

FIG. 1 is a view showing a cross section of a dummy part of a printed circuit board according to an exemplary embodiment of the present invention; FIG. 2 is a view showing the entire cross section of the printed circuit board according to an exemplary embodiment of the present invention; FIG. 3 is a view showing another printed circuit board according to another exemplary embodiment of the present invention; and FIG. 4 is a graph showing data obtained by measuring warpage of the printed circuit board according to the exemplary embodiment of the present invention.

As shown in FIGS. 1 and 2, the printed circuit board 100 according to an exemplary embodiment of the present invention is configured to include a plurality of insulating layers 30 built-up therein, the plurality of insulating layers including copper clad layers 40; a product zone 10 positioned at a central part of the insulating layers 30 and having a product mounted thereon; and a dummy zone 20 formed along a circumference of the product zone 10.

Here, although not shown in the drawings, a glass cloth may be contained in the plurality of insulating layers 30 including the copper clad layers 40 so as to increase the entire rigidity of the printed circuit board 100.

In addition, although not shown in the drawings, the printed circuit board 100 according to the present invention may have a structure in which each insulating layer 30 is built-up on both sides based on the core.

The copper clad layers 40 included in the dummy zone 20 may be spaced apart from each other at predetermined intervals so as to have a square or a rectangular shape at the edge portion of the insulating layer 30.

Therefore, the copper clad layers 40 may have a lattice shaped arrangement in which squares or rectangles having predetermined sizes, are formed at predetermined intervals when viewed from an upper surface of the insulating layer 30.

The insulating layers including the copper clad layers 40 are classified into a first insulating layer 32, a second insulating layer 34, and a third insulating layer 36 in a stacked sequence, from a lower portion of the printed circuit board.

The second insulating layer 34 including the copper clad layer is stacked on the first insulating layer 32. The second insulating layer 34 has the same size as the first insulating layer 32; however, the copper clad layer 40 of the second insulating layer 34 is arranged at a position different from that of the copper clad layer 40 of the first insulating layer 32.

That is, in the copper clad layers 40 of the first insulating layer 32 and the second insulating layer 34, the copper clad layer 40 of the second insulating layer 34 is disposed between the copper clad layers 40 of the first insulating layer 32 in an axial direction.

Similar to this, in the case in which the third insulating layer 36 is stacked on the second insulating layer 34, the copper clad layers 40 are arranged as the same as the structure in which the second insulating layer 34 is stacked on the first insulating layer 32.

Therefore, when viewed from a cross section of a state in which each insulating layer 30 is stacked, it may be appreciated that the copper clad layers 40 are alternately disposed in a right direction and an upper direction from a left side thereof.

In the case in which the copper clad layers 40 are disposed for predetermined intervals in a transverse direction and a longitudinal direction, a resin flow between the copper clad layers 40 is activated and a combination between the copper clad layers having excellent rigidity is increased, such that warpage due to a difference in coefficients of thermal expansion of each interlayer insulating layer may be decreased.

In addition, circuit patterns 12 having various shapes for installing electric devices such as multilayer ceramic capacitor (MLCC) or a central processing unit (CPU) may be formed in or on the product zone 10. Each circuit pattern 12 may be electrically connected through vias, and although not shown in the drawings, in the case in which the core is embedded, a through-via may be provided so that an upper portion of the core is connected to a lower portion thereof.

Meanwhile, it is described in the printed circuit board 100 according to the exemplary embodiment of the present invention that the copper clad layers 40 are spaced apart from each other at predetermined intervals, and disposed positions of the stacked copper clad layers 40 are arranged are different from those of lower copper clad layers 40 to thereby increase rigidity; however, in order to complement the printed circuit board 100 in view of a structure, portions of the stacked copper clad layers 40 may be partially overlapped with each other in an axial direction as shown in FIG. 3.

That is, in the printed circuit board according to the exemplary embodiment of the present invention, the copper clad layers 40 positioned in the dummy zone 20 may have a rectangular shape, respectively, and a distance between the adjacent copper clad layers 40 may be smaller than a horizontal width of the copper clad layer 40, when viewed from a cross section of the printed circuit board.

In the case in which the horizontal width of the copper clad layer 40 is larger than the distance between the adjacent copper clad layers 40, the rigidity of the dummy zone may be increased.

In particular, in the case in which portions of each copper clad layer 40 are partially overlapped with each other in an axial direction in the stacked insulating layers 30, the rigidity of the overlapped portion of the copper clad layer 40 may be increased to significantly decrease the warpage due to a difference in coefficients of thermal expansion.

In addition, the glass cloth may be contained in each insulating layer 30 to increase the rigidity of the insulating layer.

As described above, when the structure of the copper clad layer of the dummy part in the printed circuit board is improved, warpage values may be significantly decreased as shown in FIG. 4.

A graph shown in FIG. 4 shows test results of warpage on a printed circuit board having thirty insulating sheets in which the dummy structure is not improved and a printed circuit board having thirty insulating sheets in which the dummy structure is improved.

As shown in the graph, it may be appreciated that the warpage of the printed circuit board in which the dummy structure is not improved is significantly increased than that of the printed circuit board in which the dummy structure is improved.

Therefore, the printed circuit board may have the improved dummy structure to significantly increase the rigidity of the entire printed circuit board, such that reliability of the product may be significantly increased.

According to the printed circuit board according to the exemplary embodiments of the present invention, the structure of the dummy part may be improved so as to increase the warpage strength of the dummy part of the printed circuit board, such that the warpage generation of the printed circuit board may be minimized due to the increased rigidity.

In particular, copper clad layers of the insulating layers stacked in the dummy part are alternately arranged in a longitudinal direction, respectively, such that the resin flow between the copper clad layers may be activated to increase the rigidity.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A printed circuit board comprising:
a plurality of insulating layers built-up therein, the plurality of insulating layers including copper clad layers; and
a product zone and a dummy zone formed at a central part and along an edge part of the insulating layers, respectively,
wherein the copper clad layers included in each insulating layer are arranged in the dummy zone at predetermined intervals in a longitudinal direction.

2. The printed circuit board according to claim 1, wherein a glass cloth is contained in the insulating layer.

3. The printed circuit board according to claim 1, wherein the copper clad layers included in the dummy zone are arranged in a lattice shape in the dummy zone.

4. The printed circuit board according to claim 1 or 3, wherein the copper clad layers included in the dummy zone have a square shape, respectively.

5. The printed circuit board according to claim 1 or 3, wherein the copper clad layers included in the dummy zone have a rectangular shape, respectively.

6. A printed circuit board comprising:
a plurality of insulating layers built-up therein, the plurality of insulating layers including copper clad layers; and
a product zone and a dummy zone formed at a central part and along an edge part of the insulating layers, respectively,
wherein in the dummy zone, the copper clad layers included in each insulating layer are partially overlapped with each other in a longitudinal direction.

7. The printed circuit board according to claim 6, wherein a glass cloth is contained in the insulating layer.

8. The printed circuit board according to claim 7, wherein the copper clad layers included in the dummy zone have a rectangular shape, respectively.
